(19) United States
(12) Patent Application Publication
(10) Pub. No.: US 2016/0218071 A1
(43) Pub. Date: Jul. 28, 2016

(54) SMART CARD AND METHOD OF MANUFACTURING SMART CARD

(71) Applicants: Ki-bum Nam, Suwon-si (KR); Ji-myung Na, Suwon-si (KR)

(72) Inventors: Ki-bum Nam, Suwon-si (KR); Ji-myung Na, Suwon-si (KR)

(21) Appl. No.: 14/955,436

(22) Filed: Dec. 1, 2015

(30) Foreign Application Priority Data
Jan. 22, 2015 (KR) 10-2015-0010552

(51) Int. Cl. H01L 23/00; H01L 27/02; H01L 49/02

(52) U.S. Cl. CPC H01L 23/576; H01L 28/60; H01L 27/0207

(57) ABSTRACT

An integrated circuit includes a detector circuit including a sensor configured to sense an alteration to a physical characteristic of a substrate and to generate an alarm signal indicating such alteration and a circuit configured to respond to the generation of the alarm signal by implementing countermeasures. A smart card may include such a circuit to counteract a back side attack.

### CROSS-REFERENCE TO RELATED APPLICATION

This application claims the benefit of Korean Patent Application No. 10-2015-0010552, filed on Jan. 22, 2015, in the Korean Intellectual Property Office, the disclosure of which is incorporated herein in its entirety by reference,

### BACKGROUND

Inventive concepts relate to a smart card, and more particularly, to a smart card in which a circuit arranged in the smart card or data stored in the smart card may be protected from being hacked, and a method of manufacturing the smart card.

Examples of a method of physically hacking a semiconductor device (for example, a semiconductor chip or a smart card) include a method of approaching a semiconductor chip from a front side of a silicon substrate by probing and a method of creating a fault in a semiconductor chip by using a laser from a back side of a silicon substrate. Recently, a method of approaching a semiconductor chip from a back side of a silicon substrate by probing has been developed.

### SUMMARY

In exemplary embodiments in accordance with principles of inventive concepts, a smart card includes a substrate comprising a front side and a back side and having a first height between the front side and the back side; a circuit layer disposed on the front side of the substrate and including an analog block that includes a plurality of analog circuits and a digital block that includes a plurality of digital circuits; and at least one trench capacitor disposed in the substrate and having a second height extending from the front side of the substrate, wherein the second height is smaller than the first height and may be modified due to a back side attack on the substrate before other circuitry on the smart card is affected by the back side attack.

In exemplary embodiments in accordance with principles of inventive concepts, the circuit layer further includes at least one detecting circuit that is electrically connected to the at least one capacitor and detects a change in capacitance of the at least one trench capacitor, which is caused by a change in the height of the trench capacitor.

In exemplary embodiments in accordance with principles of inventive concepts, the at least one detecting circuit is a ring oscillator that includes a first terminal that is electrically connected to a first electrode of the at least one trench capacitor and a second terminal that is electrically connected to a second electrode of the at least one trench capacitor.

In exemplary embodiments in accordance with principles of inventive concepts, the at least one detecting circuit and the at least one trench capacitor are employed as at least one sensor, and the at least one trench capacitor is disposed under a field region in the analog block or under the digital block such that the at least one trench capacitor is adjacent to the at least one detecting circuit.

In exemplary embodiments in accordance with principles of inventive concepts, the at least one sensor is implemented as an intellectual property (IP) block and is disposed in the field region in the analog block or in the digital block.

In exemplary embodiments in accordance with principles of inventive concepts, the circuit layer further includes a frequency detector that is connected to the at least one sensor and detects a change in frequency caused by a change in capacitance of the at least one sensor.

In exemplary embodiments in accordance with principles of inventive concepts, the frequency detector is implemented as an intellectual property (IP) block and is disposed in the analog block.

In exemplary embodiments in accordance with principles of inventive concepts, the at least one sensor is implemented as a plurality of sensors arranged in a matrix form on the substrate.

In exemplary embodiments in accordance with principles of inventive concepts, the circuit layer further includes a logic gate that is commonly connected to the plurality of sensors and detects a change in capacitance of at least one selected from the plurality of sensors, and a frequency detector that is connected to the logic gate and detects a change in frequency caused by the change in capacitance.

In exemplary embodiments in accordance with principles of inventive concepts, the logic gate includes a NAND gate.

In exemplary embodiments in accordance with principles of inventive concepts, the circuit layer further includes a plurality of frequency detectors that are respectively connected to the plurality of sensors and detect a change in frequency caused by the change in capacitance of the plurality of sensors.

In exemplary embodiments in accordance with principles of inventive concepts, the at least one trench capacitor includes an insulating layer in a deep trench in the substrate; a first electrode on the insulating layer; a dielectric layer on the first electrode; and a second electrode on the dielectric layer.

In exemplary embodiments in accordance with principles of inventive concepts, the first and second electrodes include polysilicon.

In exemplary embodiments in accordance with principles of inventive concepts, the at least one trench capacitor further includes a barrier layer on the dielectric layer, and a seed layer on the barrier layer, and the second electrode is disposed on the second electrode.

In exemplary embodiments in accordance with principles of inventive concepts, the first electrode includes polysilicon and the second electrode includes metal.

In exemplary embodiments in accordance with principles of inventive concepts, a smart card includes a substrate; and at least one sensor including at least one trench capacitor that detects a back side attack on the substrate, wherein the at least one trench capacitor has a height that changes due to back side polishing that is performed during the back side attack.

In exemplary embodiments in accordance with principles of inventive concepts, the at least one sensor further includes a detecting circuit that is electrically connected to the at least one trench capacitor and detects a change in capacitance of the at least one trench capacitor, which is caused by a change in the height of the at least one trench capacitor.

In exemplary embodiments in accordance with principles of inventive concepts, the at least one detecting circuit is a ring oscillator that comprises a first terminal that is electrically connected to a first electrode of the at least one trench capacitor, and a second terminal that is electrically connected to a second electrode of the at least one trench capacitor.

In exemplary embodiments in accordance with principles of inventive concepts, a smart card includes a frequency detector that is connected to the at least one sensor and detects a change in frequency caused by a change in capacitance of the at least one sensor.

In exemplary embodiments in accordance with principles of inventive concepts, the at least one sensor is implemented as a plurality of sensors arranged in a matrix on the substrate.

In exemplary embodiments in accordance with principles of inventive concepts, a smart card includes a logic gate that is commonly connected to the plurality of sensors, wherein the connection is configured such that a change in capacitance of at least one selected from the plurality of sensors affects the output of the logic gate; and a frequency detector that is connected to the logic gate and detects a change in frequency caused by the change in capacitance.

In exemplary embodiments in accordance with principles of inventive concepts, the logic gate includes a NAND gate.

In exemplary embodiments in accordance with principles of inventive concepts, a smart card includes a plurality of frequency detectors that are respectively connected to the plurality of sensors and detect a change in frequency caused by a change in capacitance of the plurality of sensors.

In exemplary embodiments in accordance with principles of inventive concepts, a method of manufacturing a smart card includes forming a deep trench by etching a portion of a substrate, wherein the substrate comprises a front side and a back side and has a first height between the front side and the back side; forming a trench capacitor in the deep trench, wherein the trench capacitor has a second height extending from the front side of the substrate, and the second height is smaller than the first height, wherein the height of the trench capacitor may be modified from the second height due to a back side attack on the substrate; and forming a circuit layer on the front side of the substrate, wherein the circuit layer includes an analog block that includes a plurality of analog circuits and a digital block that includes a plurality of digital circuits.

In exemplary embodiments in accordance with principles of inventive concepts, the forming of the circuit layer further comprises forming a detecting circuit that is electrically connected to the trench capacitor in a field region in the analog block or in the digital block and detecting a change in capacitance of the at least one trench capacitor, which is caused by a change in the second height.

In exemplary embodiments in accordance with principles of inventive concepts, the trench capacitor and the detecting circuit are included in a sensor, and the forming of the circuit layer further comprises forming a frequency detector that is connected to the sensor and detecting a change in frequency caused by a change in capacitance of the at least one sensor.

In exemplary embodiments in accordance with principles of inventive concepts, the forming of the trench capacitor comprises: forming an insulating layer in a deep trench in the substrate; forming a first electrode on the insulating layer; forming a dielectric layer on the first electrode; and forming a second electrode on the dielectric layer.

In exemplary embodiments in accordance with principles of inventive concepts, the first and second electrodes comprise polysilicon.

In exemplary embodiments in accordance with principles of inventive concepts, the forming of the trench capacitor further comprises sequentially forming a barrier layer and a seed layer on the dielectric layer, and the forming of the second electrode comprises forming the second electrode on the seed layer.

In exemplary embodiments in accordance with principles of inventive concepts, the first electrode includes polysilicon and the second electrode comprises metal.

In exemplary embodiments in accordance with principles of inventive concepts, an integrated circuit includes a detector circuit including a sensor configured to sense an alteration to a physical characteristic of a substrate and to generate an alarm signal indicating such alteration; and a circuit configured to respond to the generation of the alarm signal by implementing countermeasures.

In exemplary embodiments in accordance with principles of inventive concepts, the sensor is configured to detect an alteration to the thickness of the substrate.

In exemplary embodiments in accordance with principles of inventive concepts, the sensor is configured to detect an alteration to the alteration of the thickness of the substrate by detecting an alteration to the capacitance of a capacitor.

In exemplary embodiments in accordance with principles of inventive concepts, the capacitor is a trench capacitor formed in the substrate extending toward a bottom surface of the substrate to an extent that it is affected by alterations to the substrate before other circuitry within the integrated circuit is affected by the alterations.

In exemplary embodiments in accordance with principles of inventive concepts, the detector circuit includes a trench capacitor, a ring oscillator configured to oscillate at a frequency according to the capacitance of the trench capacitor, and a frequency detector configured to monitor the frequency output of the ring oscillator and to set an alarm if the frequency output is outside a prescribed range of frequencies; and wherein the circuit configured to respond to the generation of the alarm signal is a controller that is configured to respond by implementing countermeasures that may include: a controller nullifying data stored in a memory or initiating a cryptography module,

In exemplary embodiments in accordance with principles of inventive concepts, smart card including an integrated circuit including a detector circuit that includes a trench capacitor, a ring oscillator configured to oscillate at a frequency according to the capacitance of the trench capacitor, and a frequency detector configured to monitor the frequency output of the ring oscillator and to set an alarm if the frequency output is outside a prescribed range of frequencies; and wherein the circuit configured to respond to the generation of the alarm signal is a controller that is configured to respond by implementing countermeasures that may include: a controller nullifying data stored in a memory or initiating a cryptography module.

In exemplary embodiments in accordance with principles of inventive concepts, a semiconductor device according to an aspect of the inventive concept may be a semiconductor device for protecting near field communication (NFC) security information.

### BRIEF DESCRIPTION OF THE DRAWINGS

Exemplary embodiments of the inventive concept will be more clearly understood from the following detailed description taken in conjunction with the accompanying drawings in which:

FIGS. 1A to 1F are cross-sectional views illustrating processes of attacking a back side of a smart card;

FIG. 2 is a circuit diagram of a protection device according to an exemplary embodiment;

FIG. 3A is a cross-sectional view illustrating a semiconductor device that includes a portion of a sensor, according to an exemplary embodiment;

FIG. 3B is a cross-sectional view illustrating a semiconductor device on which back side polishing is performed and includes a portion of a sensor, according to an exemplary embodiment;

FIGS. 4A to 4E are cross-sectional views illustrating an example of a method of manufacturing a trench capacitor in a sensor, according to an exemplary embodiment;

FIG. 5 is a cross-sectional view illustrating a semiconductor device that includes a trench capacitor manufactured according to the method of FIGS. 4A to 4E;

FIGS. 6A to 6F are cross-sectional views illustrating an example of a method of manufacturing a trench capacitor in a sensor, according to another exemplary embodiment;

FIG. 7 is a cross-sectional view illustrating a semiconductor device that includes a trench capacitor formed according to the method of FIGS. 6A to 6F;

FIG. 8 is a block diagram illustrating a protection device according to another exemplary embodiment;

FIG. 9 is a block diagram illustrating a protection device according to another exemplary embodiment;

FIG. 10A is a graph illustrating an output of a sensor before a back side attack, according to an exemplary embodiment, and FIG. 10B is a graph illustrating an output of a sensor after a back side attack, according to an exemplary embodiment;

FIG. 11A is a cross-sectional view illustrating a semiconductor device according to an exemplary embodiment;

FIG. 11B is a diagram of an example of a smart card chip;

FIG. 12 is a block diagram illustrating an example of a circuit layer in the semiconductor device of FIG. 11A;

FIG. 13 is a block diagram illustrating another example of a circuit layer in the semiconductor device of FIG. 11A;

FIG. 14 is a diagram of an arrangement of a plurality of sensors according to an exemplary embodiment;

FIG. 15 is a flowchart illustrating a method of manufacturing a semiconductor device, according to an exemplary embodiment;

FIG. 16 is a flowchart illustrating a method of manufacturing a semiconductor device, according to another exemplary embodiment;

FIG. 17 is a block diagram illustrating an example of a computing system including a smart card, according to an exemplary embodiment;

FIG. 18 is a block diagram illustrating another example of a computing system including a smart card, according to an exemplary embodiment;

FIG. 19 is a block diagram illustrating another example of a computing system including a smart card, according to an exemplary embodiment; and

FIG. 20 is a block diagram illustrating another example of a computing system including a smart card, according to an exemplary embodiment.

### DETAILED DESCRIPTION OF THE EMBODIMENTS

Hereinafter, one or more exemplary embodiments will be described in detail with reference to the accompanying drawings. These exemplary embodiments are provided so that this disclosure will be thorough and complete, and will fully convey inventive concepts to those of ordinary skill in the art, As inventive concepts allow for various changes and numerous exemplary embodiments, particular exemplary embodiments will be illustrated in the drawings and described in detail in the written description. However, this is not intended to limit the inventive concept to particular modes of practice, and it is to be appreciated that all changes, equivalents, and substitutes that do not depart from the spirit and scope of exemplary embodiments are encompassed in inventive concepts. In the drawings, like reference numerals refer to like elements throughout and sizes of components in the drawings may be exaggerated for clarity, Expressions such as “at least one of,” when preceding a list of elements, modify the entire list of elements and do not modify the individual elements of the list.

The terms used in the present specification are merely used to describe particular exemplary embodiments, and are not intended to limit inventive concepts. An expression used in the singular encompasses the expression of the plural, unless it has a clearly different meaning in the context. In the present specification, it is to be understood that the terms such as “including,” “having,” and “comprising” are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

While such terms as “first,” “second,” etc., may be used to describe various components, such components must not be limited to the above terms. The above terms are used only to distinguish one component from another. Therefore, a first component may be referred to as a second component without departing from the scope of the present inventive concept, and vice versa.

Unless defined otherwise, all terms used in the exemplary embodiments including technical or scientific terms have the same meaning as generally understood by one of ordinary skill in the art. It will be further understood that terms, such as those defined in commonly used dictionaries, should be interpreted as having a meaning that is consistent with their meaning in the context of the related art, and should not be interpreted as having ideal or excessively formal meanings unless it is clearly defined in the specification.

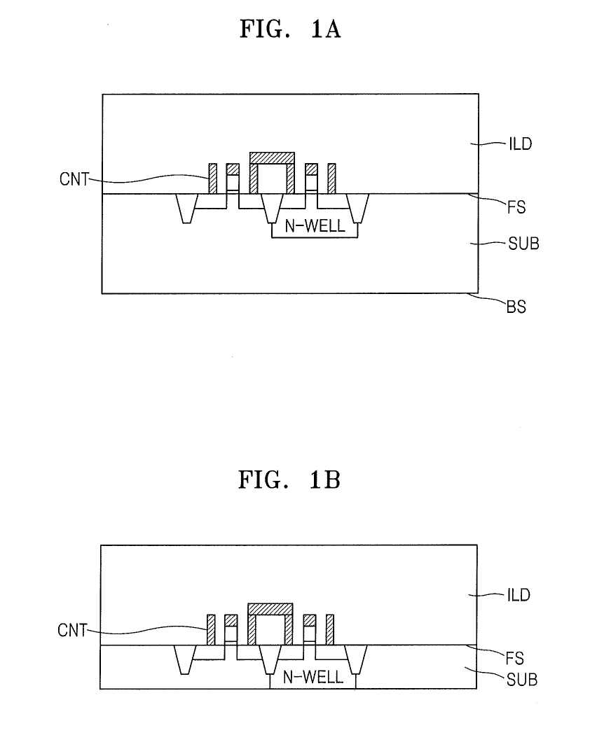

FIGS. 1A to 1F are cross-sectional views illustrating processes of attacking a back side of a smart card.

Referring to FIG. 1A, a smart card includes a plurality of circuits arranged at a front side FS of a substrate SUB. In an exemplary embodiment, the front side FS may correspond to a front surface of the substrate SUB. For example, the plurality of circuits may include an n-channel metal-oxide semiconductor (NMOS) transistor and a p-channel metal-oxide semiconductor (PMOS) transistor. A plurality of contacts CNT are disposed on the front side FS of the substrate SUB, and an insulating layer ILD is disposed on the plurality of contacts CNT.

Referring to FIG. 1B, a chemical polishing machine is used to perform back side polishing so that a back side BS of the substrate SUB is polished to a predetermined depth. In an exemplary embodiment, the back side BS may correspond to a back surface of the substrate SUB, which is opposite to the front surface of the substrate SUB. In an exemplary embodiment, at least one active area in the substrate SUB, for example, an N-type well (N-WELL) may be exposed due to the back side polishing.

Referring to FIG. 1C, a first trench T1 is formed in the substrate SUB using a focused ion beam (FIB) technique. The front side FS of the substrate SUB is exposed via the first trench T1. Referring to FIG. 1D, a second trench T2 is formed to expose a target point TG. The second trench T2 may be referred to as an access hole.

Referring to FIG. 1E, a metal MT is deposited on the target point TG. The target point TG is a conductive line, and the deposited metal MT is electrically connected to the target point TG. Referring to FIG. 1F, when a probing needle PN contacts the target point TG via the deposited metal MT, data available through the target point TG may be obtained.

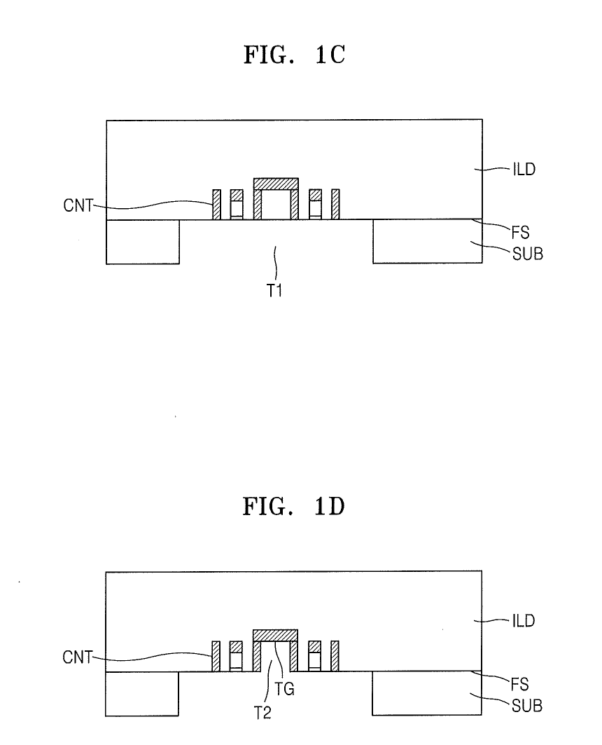

FIG. 2 is a circuit diagram of an exemplary embodiment of a protection device 10 in accordance with principles of inventive concepts.

Referring to FIG. 2, the protection device 10 may be employed to protect a semiconductor device (for example, a semiconductor chip, a micro chip, or a smart card) from a back side attack. According to the present exemplary embodiment, the protection device 10 may protect the semiconductor device from a back side attack to prevent leakage, interception, or theft of important information such as secret data or cryptographic keys stored in a memory (not shown) disposed at a front side of a semiconductor chip in a smart card, for example. A protection device 10 according an exemplary embodiment may include a sensor 11 and a frequency detector 12.

The sensor 11 may include first to third capacitors C1 to C3. According to an exemplary embodiment, at least one capacitor selected from the first to third capacitors C1 to C3 may be a trench capacitor formed in a substrate. Accordingly, in exemplary embodiments, when the back side polishing is performed during a back side attack, a lower area of the trench capacitor is removed, and thus, capacitance of the trench capacitor is changed.

Sensor 11 may also include a detecting circuit DC that detects changes in capacitance of the first to third capacitors C1 to C3. According to this exemplary embodiment, the detecting circuit DC may be a ring oscillator that includes first, second, and third PMOS transistors M3, and M5 and first, second, and third NMOS transistors M2, M4, and M6. The first PMOS transistor M1 and the first NMOS transistor M2 may form a first inverter INV1, the second PMOS transistor M3 and the second NMOS transistor M4 may form a second inverter INV2, and the third PMOS transistor M5 and the third NMOS transistor M6 may form a third inverter INV3.

Accordingly, the sensor 11 according to this exemplary embodiment may be a ring oscillator that includes first to third inverters INV1 to INV3 that are connected in series and first to third capacitors C1 to C3, that is, a multi-stage ring oscillator. Feedback related to the voltage of an output terminal OUT of the ring oscillator is transmitted to an input terminal IN.

The first capacitor C1 may be connected to an output terminal of the first inverter INV1, the second capacitor C2 may be connected to an output terminal of the second inverter INV2, and the third capacitor C3 may be connected to an output terminal of the third inverter INV3. Although not illustrated, a first resistor may be connected between the first inverter INV1 and the first capacitor C1, a second resistor may be connected between the second inverter INV2 and the second capacitor C2, and a third resistor may be connected between the third inverter INV3 and the third capacitor C3.

Although FIG. 2 illustrates that the sensor 11 includes three inverters (INV1, INV2, and INV3) and three capacitors (C1, C2, and C3), inventive concepts are not limited thereto. The number of the inverters and the number of capacitors included in the sensor 11 may vary.

The frequency detector 12 may be connected to the output terminal OUT of the sensor 11 to detect the frequency of an output signal of the sensor 11. In operation, a lower area of at least one selected from the first to third capacitors C1 to C3 may be removed due to the back side polishing that is performed during the back side attack, and as a result, the capacitance of at least one selected from the first to third capacitors C1 to C3 may be changed. When capacitance decreases, for example, the frequency of an output signal output from the sensor 11 may increase. In exemplary embodiments in accordance with principles of inventive concepts, the frequency detector 12 may detect a change in capacitance by detecting a frequency, or change in frequency, of an output signal OUT from the terminal of the same name.

In exemplary embodiments, when the frequency of output signal OUT, detected by the frequency detector 12, is outside a predetermined critical range, a control signal may be provided to a central processing unit (CPU) (not shown) in the semiconductor device. According to an exemplary embodiment, the frequency detector 12 may generate a logic “low” control signal when the detected frequency is within a critical range, and may generate a logic “high” control signal when the detected frequency is outside the critical range. The frequency detector 12 may provide a generated control signal to the CPU. For example, when a critical range is set to about 14 MHz to about 26 MHz and a detected frequency is greater than 26 MHz, the frequency detector 12 may generate a logic “high” control signal and provide the generated control signal to the CPU.

When the CPU receives the logic “high” control signal from the frequency detector 12, the CPU may nullify data stored in a memory (not shown) in the semiconductor device or initialize a function of a cryptography module (not shown) in the semiconductor device. In exemplary embodiments in accordance with principles of inventive concepts, the semiconductor device may be reset, and security information may be protected from a back side attack, in response to activation of the frequency detector signal, which, in turn, may reflect a change in capacitance in a ring oscillator.

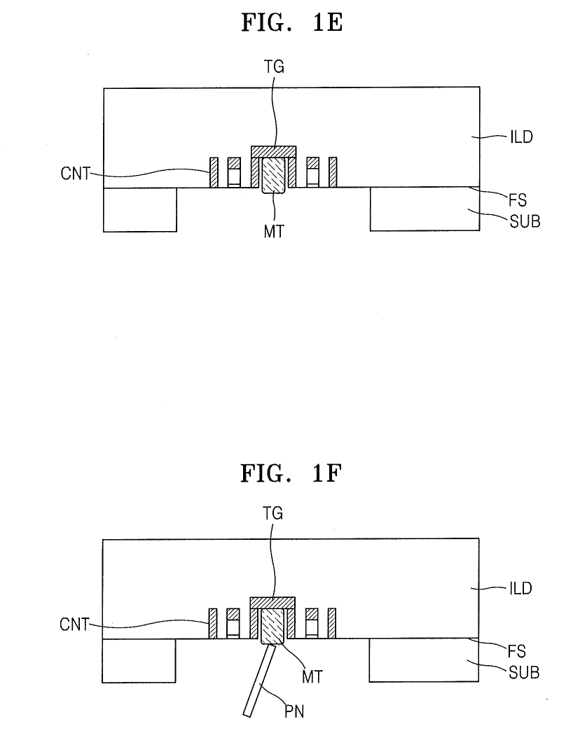

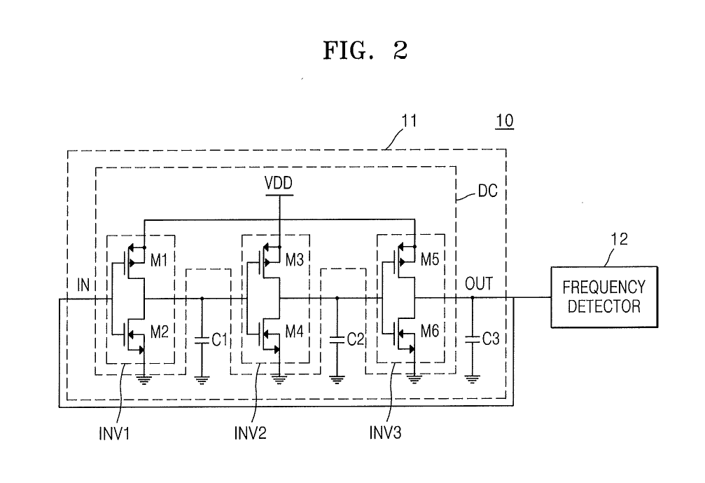

FIG. 3A is a cross-sectional view illustrating a semiconductor device 100 that includes a portion of a sensor, according to an exemplary embodiment.

Referring to FIG. 3A, the semiconductor device 100 includes a substrate 101, a trench capacitor TC in the substrate 101, and an inverter INV at a front side FS of the substrate 101. According to this exemplary embodiment, the trench capacitor TC may be one selected from the first to third capacitors C1 to C3 shown in FIG. 2, and the inverter INV may be one selected from the first to third inverters INV1 to INV3 shown in FIG. 2. According to this exemplary embodiment, the semiconductor device may be a smart card chip, that is, a semiconductor chip embedded in a smart card. The semiconductor device according to an exemplary embodiment may be a semiconductor device for protecting Near Field Communication (NFC) security information.

The substrate 101 may be a semiconductor substrate that has a first height H1 between the front side FS and a back side BS, and may include one selected from, for example, silicon, silicon-on-insulator (SOI), silicon-on-sapphire, germanium, silicon germanium, and gallium arsenide. For example, the substrate 101 may be a P-type semiconductor substrate. An isolation layer 102, which defines a plurality of active areas, is disposed in the substrate 101. The isolation layer 102 may be provided by performing, for example, a Shallow Trench Isolation (STI) process. An n-type well 103 may be disposed in a portion of the substrate 101.

In this exemplary embodiment, trench capacitor TC is disposed in the substrate 101 and has a second height H2 from the front side FS of the substrate 101. The second height H2 is smaller than the first height H1. According to this exemplary embodiment, the second height H2 may be modified due to back side polishing, such as may be performed for a back side attack.

A first gate G1, and a source 104a and a drain 104b disposed at both sides of the first gate G1 may form a PMOS transistor PM. A second gate G2, and a drain 104c and a source 104d disposed at both sides of the second gate G2 may form an NMOS transistor NM. Each of the first and second gates G1 and G2 may include a gate insulating layer 105 and a gate electrode 106.

In exemplary embodiments, the gate insulating layer 105 may be disposed on the substrate 101 via atomic layer deposition (ALD) or chemical vapor deposition (CVD). The gate insulating layer 105 may be formed of a high-k material, for example, hafnium oxide (HfO₂), hafnium silicon oxide (HfSiO), hafnium oxynitride (HfON), hafnium silicon oxynitride (HfSiON), hafnium aluminum oxide (HfAlO), hafnium lanthanum oxide (HfLaO), or lanthanum oxide (La₂O₃). Alternatively, the gate insulating layer 105 may be a dielectric material, for example, silicon oxide (SiO₂), silicon oxynitride (SiON), or silicon nitride (SiN).

In exemplary embodiments, the gate electrode 106 may be foamed on the gate insulating layer 105 via ALD, CVD, or physical vapor deposition (PVD). The gate electrode 106 may include metal or a metal alloy, for example, titanium (Ti), tantalum (Ta), tungsten (W), hafnium (Hf), molybdenum (Mo), a nitride thereof, a carbide thereof, a silicide thereof, or a silicide nitride thereof.

A first source contact 107a may be disposed on the source 104a of the PMOS transistor PM, and a power voltage VDD may be applied to the first source contact 107a. A first drain contact 107b may be disposed on the drain 104b of the PMOS transistor PM, a second drain contact 107c may be disposed on the drain 104b of the NMOS transistor NM, and the first and second drain contacts 107a and 107b may be electrically connected to each other via a first conductive line ML1. A second source contact 107d may be disposed on the source 104d of the NMOS transistor NM. The second source contact 107d may be grounded.

A first gate contact 108a may be disposed on the first gate G1, a second gate contact 108b may be disposed on the second gate G2, and the first and second gate contacts 108a and 108b may be electrically connected to each other via a second conductive line ML2. However, the above-described structure of the inverter INV is only an exemplary embodiment, and the inverter INV may be modified in various ways.

FIG. 3B is a cross-sectional view illustrating a semiconductor device 100′ which includes a portion of a sensor, according to an exemplary embodiment and upon which backside polishing may be performed in the course of a back side attack.

Referring to FIG. 3B, when back side polishing is performed during a back side attack, a predetermined depth may be removed from a back side of the substrate 101. Accordingly, a lower end of a trench capacitor TC may be cut. In this case, a second height H2′ of the trench capacitor TC may be changed. As a result, as the dielectric material of the trench capacitor TC decreases, the capacitance of the trench capacitor TC may decrease and a frequency of an output signal of a sensor may increase. A system and method in accordance with principles of inventive concepts may detect such a change in capacitance, as exhibited in a change in signal frequency, to counteract a back side attack.

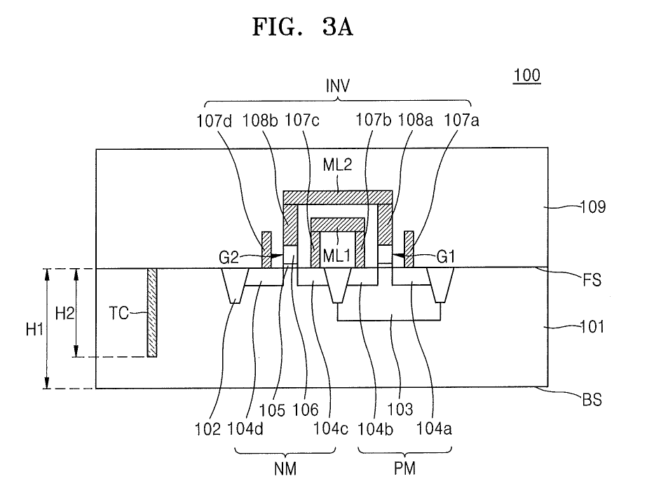

FIGS. 4A to 4E are cross-sectional views illustrating an example of a method of manufacturing a trench capacitor in a sensor in accordance with principles of inventive concepts.

Referring to FIG. 4A, a plurality of deep trenches DT1, DT2, and DT3 having a first depth D1 from a front side FS of a substrate 101 are formed by etching a portion of the substrate 101. For example, the substrate 101 may be a silicon substrate. In such an embodiment, the plurality of deep trenches DT1, DT2, and DT3 may be formed by etching the substrate 101. Respective first depths D1 and respective first widths W1 of the plurality of deep trenches DT1, DT2, and DT3 may vary according to a capacitance of a capacitor to be manufactured. According to the present exemplary embodiment, the first depth D1 may be greater than a height (for example, the second height H2′ of FIG. 3B) to which the substrate 101 is reduced due to back side polishing performed in the course of a back side attack. That is, the depth D1 of the trenches may be great enough to expose the trenches in response to back side polishing performed during a back side attack.

Next, an insulating layer 110 is formed on the substrate 101 in which the plurality of deep trenches DT1, DT2, and DT3 are formed. The insulating layer 110 may be deposited on the substrate 101 via low pressure chemical vapor deposition (LPCVD). In exemplary embodiments, the insulating layer 110 may be deposited to have a thickness of about 1.5 μm. A capacitor to be manufactured may be separated from the substrate 101 because of the insulating layer 110.

Referring to FIG. 4B, a first electrode 111 may be formed on the insulating layer 110. The first electrode 111 may be deposited on the insulating layer 110 via LPCVD. For example, the first electrode 111 may include polysilicon. Although not illustrated, the method of manufacturing the trench capacitor may further include doping a material that forms an electrode (for example, boron) on portions of the first electrode 111 which correspond to inner areas of the plurality of deep trenches DT1, DT2, and DT3.

Referring to FIG. 4C, a dielectric layer 112 may be formed on the first electrode 111. The dielectric layer 112 may be deposited on the first electrode 111 via LPCVD. The dielectric layer 112 may be a single layer or multiple layers formed of at least one selected from silicon oxide (SiO₂), silicon nitride (Si₃N₄), silicon oxynitride (SiON), hafnium oxide (HfO₂), hafnium silicon oxide (HfSiₓO_{y}), aluminum oxide (Al₂O₃), and zirconium oxide (ZrO₂).

Referring to FIG. 4D, a second electrode 113 may be formed on the dielectric layer 112. The second electrode 113 may be deposited on the dielectric layer 112 via LPCVD, and then, for example, annealed at a temperature of about 1050° C. For example, the second electrode 113 may include polysilicon.

Referring to FIG. 4E, a portion of the first electrode 111 on the front side FS of the substrate 101 may be exposed to farm a contact related to the first electrode 111. Although not illustrated, a first contact related to the first electrode 111 may be formed on an exposed upper portion of the first electrode 111, and a second contact related to the second electrode 113 may be formed on an upper portion of the second electrode 113. The first contact may be connected to a first terminal of a ring oscillator, and the second contact may be connected to a second terminal of the ring oscillator. According to the present exemplary embodiment, the trench capacitor may be manufactured by a CMOS process.

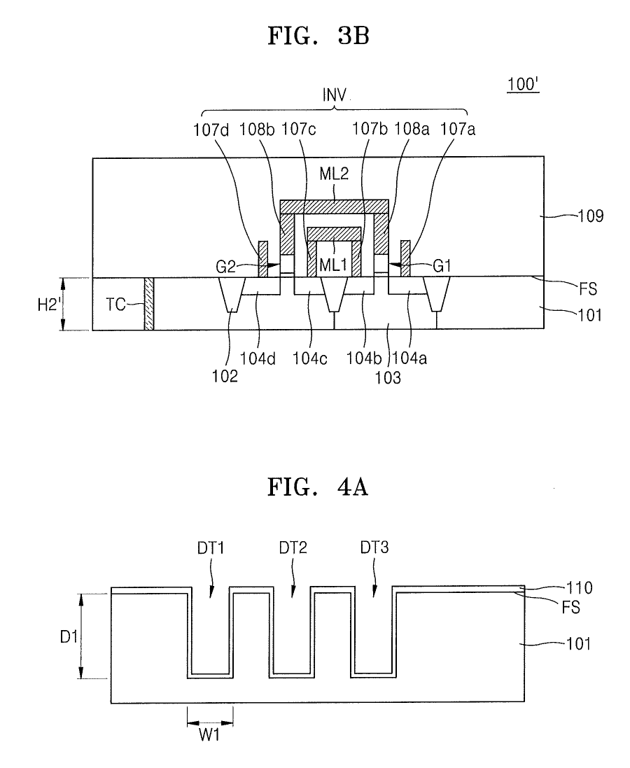

FIG. 5 is a cross-sectional view illustrating a semiconductor device 100a that includes the trench capacitor manufactured according to the method of FIGS. 4A to 4E.

Referring to FIG. 5, the semiconductor device 100a may include a deep trench capacitor TCa and a ring oscillator ROa. The deep trench capacitor TCa and the ring oscillator ROa may be employed as a sensor. According to this exemplary embodiment, the semiconductor device 100a may be a smart card chip, that is, a semiconductor chip embedded in a smart card, for example.

The deep trench capacitor TCa may be formed in a substrate 101 by the method shown in FIGS. 4A to 4E, for example. The ring oscillator ROa may be formed near the deep trench capacitor TCa on the substrate 101. According to an exemplary embodiment, a first contact CNT1 on a first electrode 111 may be connected to a first terminal M1c (for example, a+ terminal) of the ring oscillator ROa, and a second contact CNT2 of a second electrode 113 may be connected to a second terminal M1d (for example, a− terminal) of the ring oscillator ROa.

In exemplary embodiments, first conductive patterns M1a and M1b may be respectively disposed on the first and second contacts CNT1 and CNT2 that are respectively connected to the first and second electrodes 111 and 113. Via plugs V may be disposed on each of the first conductive patterns M1a and M1b and the first and second terminals M1c and M1d of the ring oscillator ROa. The via plug V on the first conductive pattern M1a and the via plug V on the first terminal M1c of the ring oscillator ROa may be electrically connected to each other via a third conductive pattern M3. The via plug V on the second conductive pattern M1b and the via plug V on the second terminal M1d of the ring oscillator ROa may be electrically connected to each other via a second conductive pattern M2.

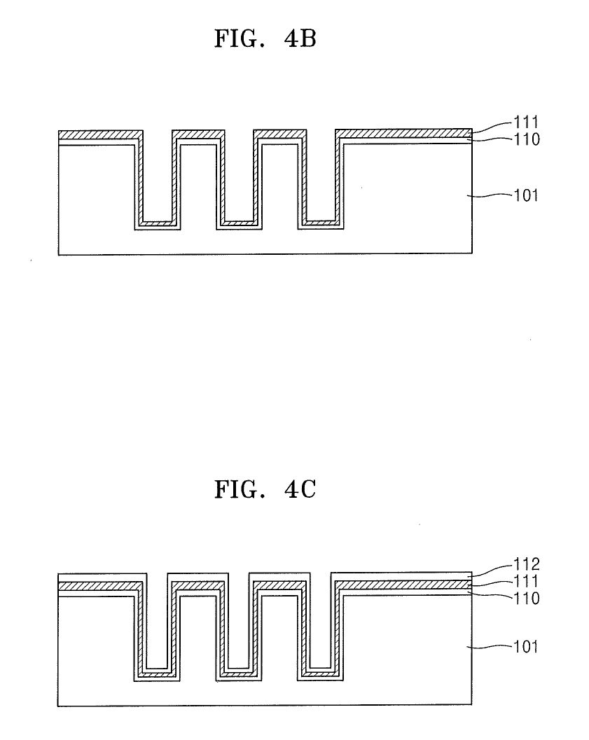

FIGS. 6A to 6F are cross-sectional views illustrating an exemplary embodiment of a method of manufacturing a trench capacitor in a sensor in accordance with principles of inventive concepts.

Referring to FIG. 6A, a plurality of deep trenches DT1, DT2, and DT3, which are formed to a first depth D1 from a front side FS of the substrate 101, are formed by etching a portion of a substrate 101. In exemplary embodiments, the substrate 101 may be a silicon substrate. In such embodiments, the plurality of deep trenches DT1, DT2, and DT3 may be formed by etching the substrate 101. Respective first depths D1 and respective first widths W1 of the plurality of deep trenches DT1, DT2, and DT3 may vary according to the value of capacitor to be manufactured. According to this exemplary embodiment, the first depth D1 may be greater than a height (for example, the second height H2′ of FIG. 3B) of the substrate 101 which is reduced due to the back side polishing.

Next, an insulating layer 110 is formed on the substrate 101 in which the plurality of deep trenches DT1, DT2, and DT3 are formed. The insulating layer 110 may be deposited on the substrate 101 via LPCVD. For example, the insulating layer 110 may be deposited to have a thickness of about 1.5 μm. A capacitor to be manufactured may be separated from the substrate 101 because of the insulating layer 110.

Referring to FIG. 6B, a first electrode 111 may be formed on the insulating layer 110. The first electrode 111 may be deposited on the insulating layer 110 via LPCVD. For example, the first electrode 111 may include polysilicon. Although not illustrated, the method of manufacturing the trench capacitor may further include doping a material that forms an electrode (for example, boron) on portions of the first electrode 111 which correspond to inner areas of the plurality of deep trenches DT1, DT2, and DT3.

Referring to FIG. 6C, a dielectric layer 112 may be formed on the first electrode 111. The dielectric layer 112 may be deposited on the first electrode 111 via LPCVD. The dielectric layer 112 may be a single layer or multiple layers formed of at least one selected from SiO₂, Si₃N₄, SiON, HfO₂, HfSiₓO_{y}, Al₂O₃, and ZrO₂, for example.

Referring to FIG. 6D, a barrier layer 114 may be formed on the dielectric layer 112 via ALD, CVD, or PVD. The barrier layer 114 may include metal or a metal alloy, for example, Ti, Ta, W, Hf, Mo, a nitride thereof (for example, TiN, TaN, WN, HfN, Mo₂N), a carbide thereof (for example, TiC, TaC, WC, HfC, Mo₂C), a silicide thereof (for example, TiSi₂, WSi₂, TaSi₂, HfSi₂, MoSi₂), or a silicide nitride thereof (for example, TiSiN, WSiN, TaSiN, HfSiN, MoSiN).

A seed layer 115 may be formed on the barrier layer 114 via ALD, CVD, or PVD. The seed layer 115 may include at least one selected from aluminum (Al), gold (Au), beryllium (Be), bismuth (Bi), cobalt (Co), copper (Cu), Hf, indium (In), manganese (Mn), Mo, nickel (Ni), lead (Pb), palladium (Pd), platinum (Pt), rhodium (Rh), rhenium (Re), ruthenium (Ru), Ta, tellurium (Te), Ti, W, zinc (Zn), and zirconium (Zr).

Referring to FIG. 6E, a second electrode 116 may be formed on the seed layer 115. The second electrode 116 may be a metal layer formed of, for example, copper. According to an exemplary embodiment in accordance with principles of inventive concepts, the second electrode 116 may be formed on the seed layer 115 by performing electroplating to fill copper.

Referring to FIG. 6F, a portion of the first electrode 111 on the front side FS of the substrate 101 may be exposed to form a contact related to the first electrode 111. Although not illustrated, a first contact related to the first electrode 111 may be formed on an exposed upper portion of the first electrode 111, and a second contact related to the second electrode 116 may be formed on an upper portion of the second electrode 116. The first contact may be connected to a first terminal of a ring oscillator, and the second contact may be connected to a second terminal of the ring oscillator.

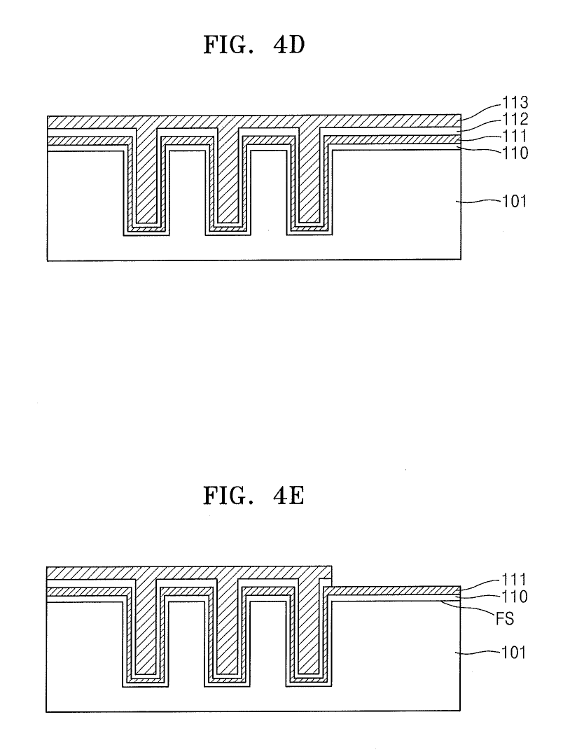

FIG. 7 is a cross-sectional view illustrating an exemplary embodiment of a semiconductor device 100b that includes a trench capacitor formed according to the method of FIGS. 6A to 6F.

Referring to FIG. 7, the semiconductor device 100b may include a deep trench capacitor TCb and a ring oscillator ROb. The deep trench capacitor TCb and the ring oscillator ROb may be employed as a sensor. According to this exemplary embodiment, the semiconductor device 100b may be a smart card chip, that is, a semiconductor chip embedded in a smart card, for example.

The deep trench capacitor TCb may be formed in a substrate 101 using the method shown in FIGS. 6A to 6F. The ring oscillator ROb may be formed near the deep trench capacitor TCb on the substrate 101.

According to an exemplary embodiment, a first contact CNT1 on a first electrode 111 may be electrically connected to a first terminal M1c (for example, a+ terminal) of the ring oscillator ROa, and a second contact CNT2 of a second electrode 116 may be electrically connected to a second terminal M1d (for example, a− terminal) of the ring oscillator ROa.

In exemplary embodiments, first conductive patterns M1a and M1e may be respectively disposed on the first and second contacts CNT1 and CNT2 that are respectively connected to the first and second electrodes 111 and 116. Via plugs V may be disposed on each of the first conductive patterns M1a and M1e and the first and second terminals M1c, M1d of the ring oscillator ROa. The via plug V on the first conductive pattern M1a and the via plug V on the first terminal M1c of the ring oscillator ROa may be electrically connected to each other via a second conductive pattern M2. The via plug V on the second conductive pattern M1e and the via plug V on the second terminal M1d of the ring oscillator ROa may be electrically connected to each other via a third conductive pattern M3.

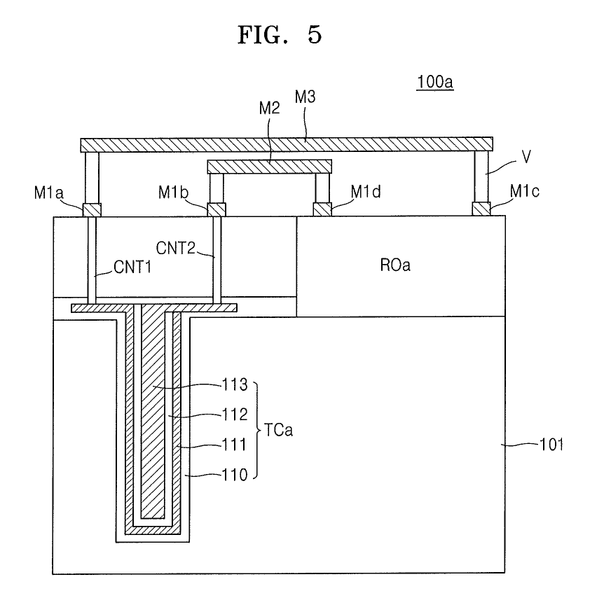

FIG. 8 is a block diagram illustrating an exemplary embodiment of a protection device 20 in accordance with principles of inventive concepts.

Referring to FIG. 8, the protection device 20 may include a sensing unit 21, a logic gate 22, and a frequency detector 23.

The sensing unit 21 may include first to twelfth sensors S1 to S12. In accordance with principles of inventive concepts, the sensing unit 21 may detect a back side attack when back side polishing is being performed on a portion of a substrate of a semiconductor device, and thereby prevent security information leakage, also referred to herein as data theft. Respective output terminals of the first to twelfth sensors S1 to S12 are connected to one another. The first to twelfth sensors S1 to S12 may be arranged, for example, in a chain form.

Each of the first to twelfth sensors S1 to S12 may be substantially similar to the sensor 11 shown in FIG. 2. In other words, each of the first to twelfth sensors S1 to S12 may be a ring oscillator that includes at least one trench capacitor. For brevity and clarity of description, features of the sensor 11 described with reference to FIG. 2, which may also be applied to the first to twelfth sensors S1 to S12 according to this exemplary embodiment, will not be repeated in detail here.

According to an exemplary embodiment, the first to twelfth sensors S1 to S12 may be arranged in a matrix form. Specifically, the first to twelfth sensors S1 to S12 may be arranged in a chain matrix form, for example. According to another exemplary embodiment, the first to twelfth sensors S1 to S12 may be randomly arranged on the semiconductor device. Additionally, the number of the first to twelfth sensors S1 to S12 may vary according to exemplary embodiments.

According to an exemplary embodiment, the first to twelfth sensors S1 to S12 may be arranged on a logic area of the semiconductor device. In particular, each of the first to twelfth sensors S1 to S12 may be arranged in an empty space (that is, an area unused by the basic functional circuitry of the device) within the logic area, for example. According to another exemplary embodiment, the first to twelfth sensors S1 to S12 may be arranged in any empty space on the semiconductor device.

According to an exemplary embodiment, each of the first to twelfth sensors S1 to S12 may be provided as a standard cell. Accordingly, a layout of the first to twelfth sensors S1 to S12 may be designed by, for example, auto placement and routing. According to a method of designing a standard cell layout, repeatedly used devices such as OR gates or AND gates are designed as standard cells in advance and stored in a computer system, and during a layout design process, the standard cells are placed in necessary locations and routed. Thus, a layout may be designed in a relatively short time. That is, in exemplary embodiments in accordance with principles of inventive concepts, sensors in accordance with principles of inventive concepts may be designed as standard cells and stored for use during a layout design process in order to accelerate a circuit layout design process.

According to exemplary embodiments, the first to twelfth sensors S1 to S12 may be intellectual property (IP) blocks. According to an exemplary embodiment, at least one selected from the first to twelfth sensors S1 to S12 may be arranged in a digital block. According to another exemplary embodiment, at least one selected from the first to twelfth sensors S1 to S12 may be arranged in a field area in an analog block.

The logic gate 22 may be commonly connected to the first to twelfth sensors S1 to S12 and detect a change in capacitance of at least one of the first to twelfth sensors S1 to S12. In exemplary embodiments, the logic gate 22 may detect a change in capacitance of at least one trench capacitor that is included in at least one of the first to twelfth sensors S1 to S12. According to the present exemplary embodiment, the logic gate 22 may be a NAND gate 22, and the respective output terminals of the first to twelfth sensors S1 to S12 may be connected to an input terminal of the NAND gate 22. Accordingly, when the capacitance changes in at least one of the first to twelfth sensors S1 to S12, an output of the NAND gate 22 may be logic “high.”

The frequency detector 23 may be connected to an output terminal of the logic gate 22 and detect frequency from the output of the logic gate 22. When the capacitance changes in at least one of the first to twelfth sensors S1 to S12, the frequency detector 23 may detect a frequency that is modified according to the change in capacitance.

For example, when a lower portion of a trench capacitor in the first sensor S1 is cut due to partial back side polishing, the capacitance of the trench capacitor in the first sensor S1 may decrease. In this case, capacitance of respective trench capacitors in the second to twelfth sensors S2 to S12 does not change. The logic gate 22 may nevertheless detect a reduction of the capacitance of the first sensor S1 and output logic “high,” and the frequency detector 23 may detect increased frequency.

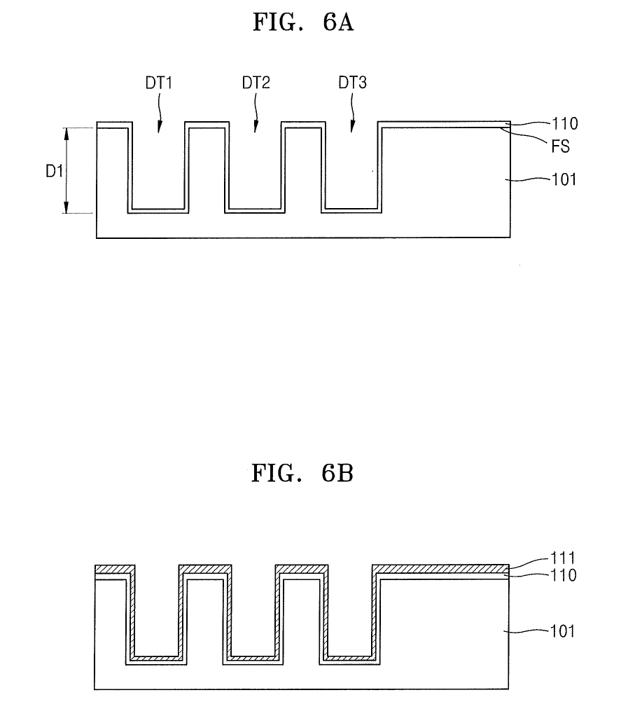

FIG. 9 is a block diagram illustrating an exemplary embodiment of a protection device 30 in accordance with principles of inventive concepts.

Referring to FIG. 9, the protection device 30 may include a sensing unit 31 and a frequency detector 32.

The sensing unit 31 may include first to twelfth sensors S1 to S12. Accordingly, the sensing unit 31 may detect a back side attack even when back side polishing is being performed on only a portion of a substrate of a semiconductor device, and thus prevent security information leakage, also referred to herein as data theft, which may include the theft of data and/or security information, such as security codes. Each of the first to twelfth sensors S1 to S12 may be substantially similar to the sensor 11 shown in FIG. 2. That is, each of the first to twelfth sensors S1 to S12 may be a ring oscillator that includes at least one trench capacitor. For clarity and brevity of explanation, features of the sensor 11 described with reference to FIG, 2, which may also be applied to the first to twelfth sensors S1 to S12 according to the present exemplary embodiment, will not be repeated in detail here.

According to an exemplary embodiment, the first to twelfth sensors S1 to S12 may be arranged in a matrix form, for example. According to another exemplary embodiment, the first to twelfth sensors S1 to S12 may be randomly arranged on a semiconductor device. The number of the first to twelfth sensors S1 to S12 may vary according to exemplary embodiments.

According to an exemplary embodiment, the first to twelfth sensors S1 to S12 may be arranged within a logic area of the semiconductor device. Each of the first to twelfth sensors S1 to S12 may be arranged in an empty space in the logic area, for example. According to another exemplary embodiment, the first to twelfth sensors S1 to S12 may be arranged in any empty space on the semiconductor device.

According to an exemplary embodiment, each of the first to twelfth sensors S1 to S12 may be provided as a standard cell. Accordingly, a layout of the first to twelfth sensors S1 to S12 may be designed by, for example, auto placement and routing.

According to the present exemplary embodiment, the first to twelfth sensors S1 to S12 may be IP blocks. An IP block may be a reusable unit of logic, cell, or chip layout design, which may be used as a building block in chip design, such as within application specific integrated circuit (ASIC) or field programmable array (FPGA) designs, for example.

According to an exemplary embodiment, at least one selected from the first to twelfth sensors S1 to S12 may be arranged in a digital block. According to another exemplary embodiment, at least one selected from the first to twelfth sensors S1 to S12 may be arranged in a field area in an analog block.

The frequency detector 32 may include first to twelfth frequency detectors FD1 to FD12. Each of the first to twelfth frequency detectors FD1 to FD12 may be substantially similar to the frequency detector 12 shown in FIG. 2. For brevity and clarity of explanation, features of the frequency detector 12 described with reference to FIG. 2, which may also be applied to the first to twelfth frequency detectors FD1 to FD12 according to the present exemplary embodiment, will not be repeated in detail here.

According to the present exemplary embodiment, the first to twelfth sensors S1 to S12 may be respectively connected to corresponding frequency detectors FD1 to FD12. Accordingly, each of the frequency detectors FD1 to FD12 may detect a frequency of an output signal of each of the first to twelfth sensors S1 to S12, and thus detect a change in capacitance of each of the first to twelfth sensors S1 to S12. For example, when a lower portion of a trench capacitor in the first sensor S1 is cut due to partial back side polishing, the capacitance of the trench capacitor in the first sensor S1 may decrease. In this case, capacitance of respective trench capacitors in the second to twelfth sensors S2 to S12 does not change. Nevertheless, the first frequency detector FD1 may detect an increased frequency of an output signal of the first sensor S1. The second to twelfth frequency detectors FD2 to FD12 may detect unchanged frequencies of output signals of the second to twelfth sensors S2 to S12. Similarly, any of the other detectors FD2-FD12 may detect a capacitance change associated with back side polishing in their own regions.

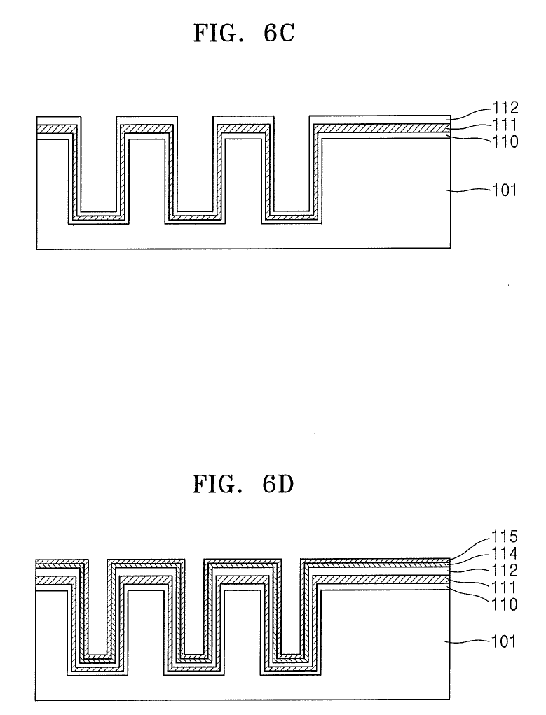

FIG. 10A is a graph illustrating an output of a sensor before a back side attack, according to an exemplary embodiment, and FIG. 10B is a graph illustrating an output of a sensor after a back side attack, in accordance with principles of inventive concepts.

Referring to FIGS. 10A and 10B, an X-axis indicates time and a Y-axis indicates a voltage level. The sensor according to the present exemplary embodiment may be, for example, the sensor 11 of FIG. 2, Hereinafter, an output frequency detection processor of the sensor will be described with reference to FIGS. 2, 10A, and 10B.

An initial capacitance of each of the first to third capacitors C1 to C3 may be about 1 pF. When a back side attack is not performed on the semiconductor device, a first period P1 of an output signal of the sensor 11 may be, for example, about 95.31 ns, as shown in FIG. 10A. However, when lower portions of the first to third capacitors C1 to C3 are cut due to a back side attack performed on the semiconductor device and thus capacitance of the first to third capacitors C1 to C3 decrease to about 0.5 pF, a second period P2 of an output signal of the sensor 11 may be, for example, 48.35 ns, as shown in FIG. 10B.

In exemplary embodiments in accordance with principles of inventive concepts, the frequency detector 12 may detect a period or a frequency of the output signal of the sensor 11, and when the frequency increases, the frequency detector 12 may determine that the capacitance of the sensor 11 has decreased, indicative of a back side attack. When the detected frequency is outside a predetermined range, a CPU may nullify data stored in a memory in the semiconductor device or initialize a function of a cryptography module in the semiconductor device to counter the back side attack. In exemplary embodiments in accordance with principles of inventive concepts, the semiconductor device may be reset, and security information may be protected from a back side attack.

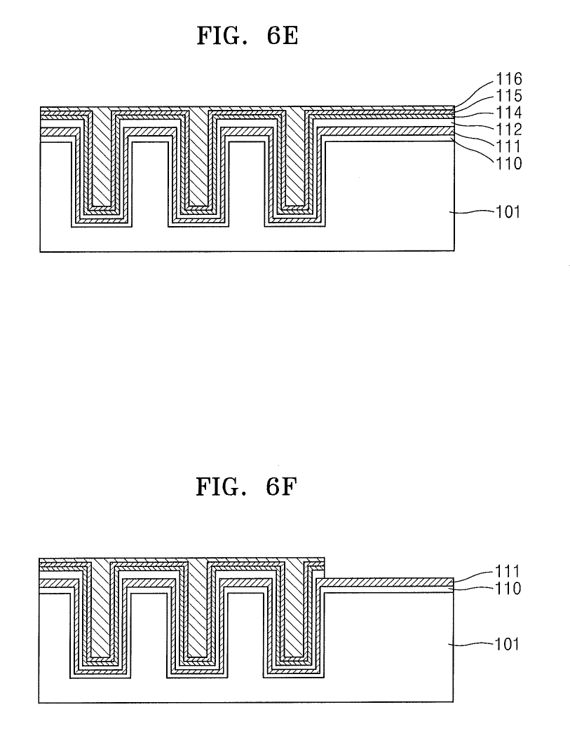

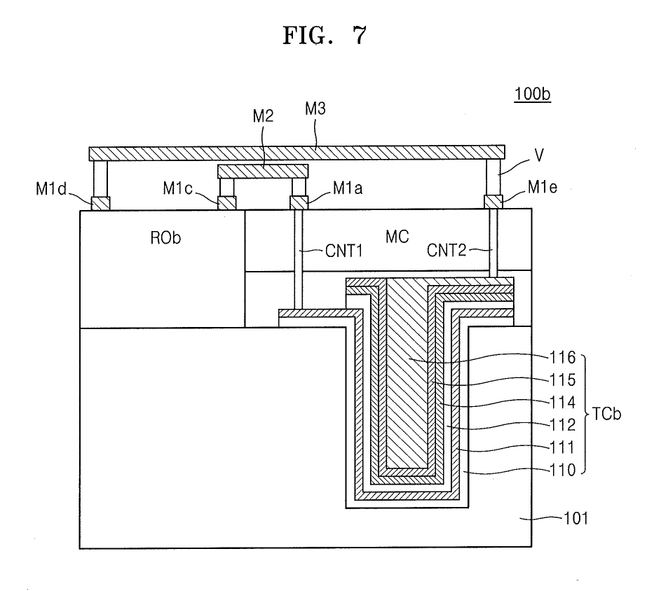

FIG. 11A is a cross-sectional view illustrating an exemplary embodiment of a semiconductor device 100c in accordance with principles of inventive concepts.

Referring to FIG. 11A, the semiconductor device 100c may include a substrate 101, a plurality of trench capacitors TC arranged in the substrate 101, a circuit layer 120 disposed at a front side FS of the substrate 101, and a protection layer 130 disposed on an upper portion of the circuit layer 120. In exemplary embodiments in accordance with principles of inventive concepts, the protection layer 130 may be provided as an active shield. Protection layer 130 may include a plurality of wires arranged on the circuit layer 120 and an insulating layer on the plurality of wires.

FIG. 11B is a diagram of an example of a smart card chip.

Referring to FIG. 11B, the semiconductor device 100c according to an exemplary embodiment may be a smart card chip, that is, a semiconductor chip embedded in a smart card. By smart card we mean any card with embedded integrated circuits (ICs), which may also be referred to as an IC card.

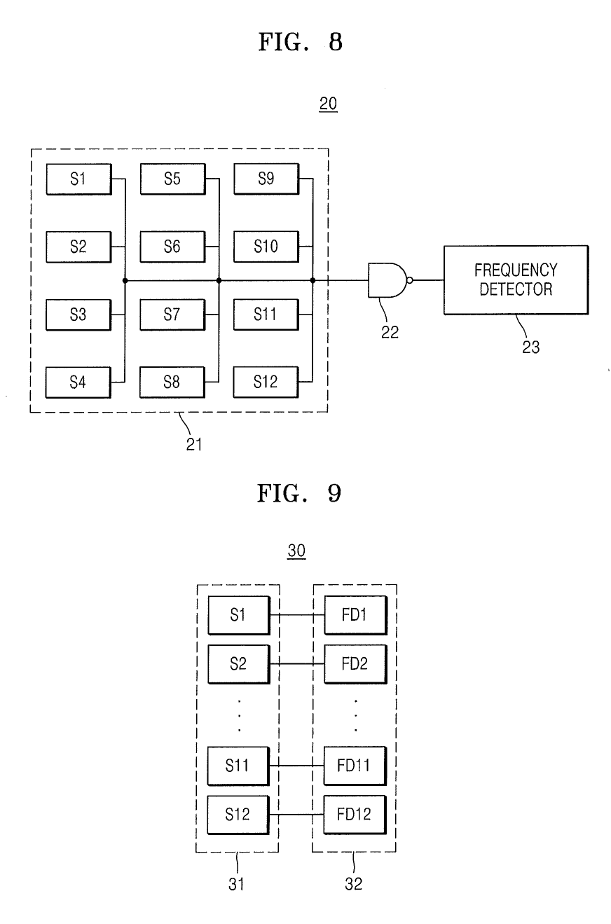

FIG. 12 is a block diagram illustrating an example of a circuit layer 120a in the semiconductor device of FIG. 11A.

Referring to FIG. 12, the circuit layer 120a may include a sensor 121, a frequency detector 122, a CPU 123, a cryptography module 124, a random number generator (RNG) 125, a communication module 126, a nonvolatile memory (NVM) 127, SRAM 128, and ROM 129. However, the circuit layer 120a is not limited thereto. The circuit layer 120a may include other function blocks, and may not include at least one of the function blocks shown in FIG. 12.

Hereinafter, referring to FIGS. 11A and 12, an exemplary embodiment of semiconductor device 100c in accordance with principles of inventive concepts will be described in detail.

The sensor 121 may include a plurality of trench capacitors TC. When a lower area of a trench capacitors TC is removed, in the course of back side polishing, the capacitance of the affected trench capacitor TC may change. The sensor 121 may be substantially similar to the sensor 11 shown in FIG. 3, the sensing unit 21 shown in FIG. 8, or the sensing unit 31 shown in FIG. 9.

The frequency detector 122 may be connected to an output terminal of the sensor 121 and detect a frequency of an output signal of the sensor 121. In exemplary embodiments in accordance with principles of inventive concepts, when the detected frequency of the output signal is outside a critical range, the frequency detector 122 may activate an alarm signal, by generating a logic “high” control signal, for example, and provide the generated control signal to the CPU 123. The frequency detector 122 may be substantially similar to the frequency detector 12 shown in FIG. 3, the frequency detector 23 shown in FIG. 8, or the frequency detector 32 shown in FIG. 9.

The CPU 123 may control overall operations of the function blocks in the semiconductor device 100c and, in accordance with principles of inventive concepts, when the alarm signal, which may be referred to herein as an intrusion alarm, is activated, the CPU may take protective measures. For example, if, in an exemplary embodiment, a logic “high” control signal is received from the frequency detector 122, the CPU 123 may nullify data stored in the NVM 127, the SRAM 128, or the ROM 129 in the semiconductor device 100c, or initialize functions of the cryptography module 124 or the RNG 125 in the semiconductor device 100c. In this manner, the semiconductor device 100c may be reset, and security information may be protected from a back side attack.

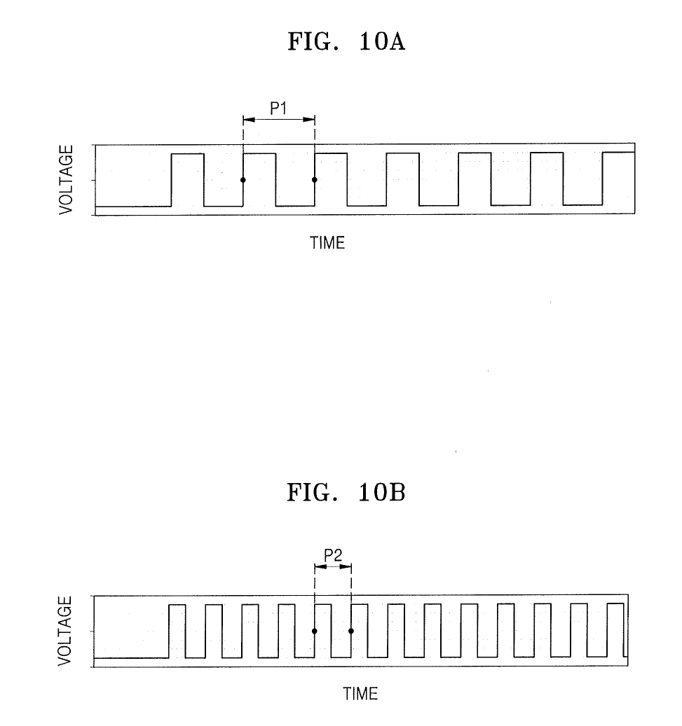

FIG. 13 is a block diagram illustrating another example of a circuit layer 120b in an exemplary embodiment of a semiconductor device in accordance with principles of inventive concepts, such as semiconductor device 100c of FIG. 11A.

Referring to FIG. 13, the circuit layer 120b may include an analog block AB that includes a plurality of analog circuits and a digital block DB that includes a plurality of digital circuits.

The analog block AB may include, for example, the frequency detector 122 of FIG. 12, a voltage detector, a light detector, or a laser detector. In exemplary embodiments in accordance with principles of inventive concepts, the frequency detector 122 may be provided as IP blocks and arranged in the analog block AB. According to this exemplary embodiment, the sensor 121 may be provided as an IP block and arranged in a field area in the analog block AB.

The digital block DB may include, for example, the CPU 123, the cryptography module 124, or the communication module 126 shown in FIG. 12. In accordance with principles of inventive concepts, the sensor 121 may be provided as an IP block and arranged in the digital block DB.

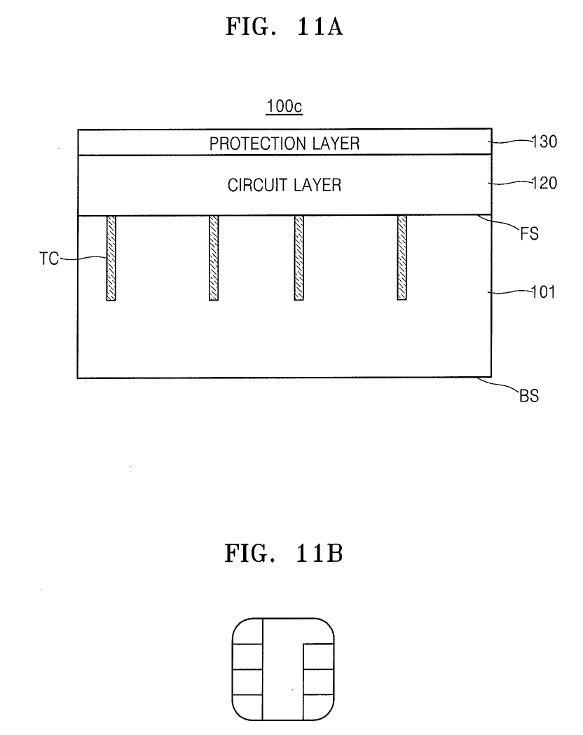

FIG. 14 is a diagram of an arrangement of first to sixth sensors S1 to S6 according to an exemplary embodiment,

Referring to FIG. 14, a semiconductor device 100d may include the first to sixth sensors S1 to S6. The semiconductor device 100d according to an exemplary embodiment may include the circuit layer 120b shown in FIG. 13, Although six sensors are illustrated in FIG. 14, the number of sensors may vary.

According to an exemplary embodiment, the first to fifth sensors S1 to S5 may be arranged in a digital block DB. A plurality of standard cells SC may be arranged in the digital block DB. According to an exemplary embodiment, each of the first to fifth sensors S1 to S5 may be provided as IP blocks and arranged in the digital block DB. Accordingly, trench capacitors TC1 to TC5 respectively included in the first to fifth sensors S1 to S5 may be disposed under the digital block DB.

According to an exemplary embodiment, the sixth sensor S6 may be disposed in a field region FR in an analog block AB. According to an exemplary embodiment, the sixth sensor S6 may be provided as IP blocks and disposed in the field region FR in the analog block AB. As a result, a trench capacitor TC6 in the sixth sensor S6 may be disposed under the field region FR in the analog block AB.

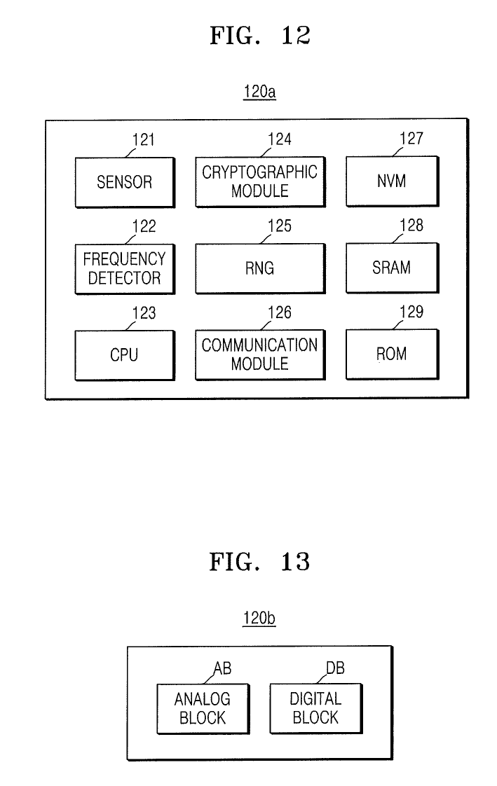

FIG. 15 is a flowchart illustrating an exemplary method of manufacturing a semiconductor device in accordance with principles of inventive concepts.

Referring to FIG. 15, an exemplary method of manufacturing a semiconductor device in accordance with principles of inventive concepts may be a method of manufacturing, for example, the semiconductor device 100 shown in FIG. 3A, the semiconductor device 100a shown in FIG. 5, the semiconductor device 100b shown in FIG. 7, or the semiconductor device 100c shown in FIG. 11A. As a result, the features described with reference to FIGS. 2 to 14 may also be applied to the present exemplary embodiment. According to the present exemplary embodiment, the semiconductor device may be a smart card chip, that is, a semiconductor chip embedded in a smart card.

In operation S100, a deep trench is formed by etching a portion of a substrate. The substrate includes a front side and a back side and has a first height between the first and second sides. The depth of the deep trench may be greater than the height of the substrate remaining after it is reduced due to back side polishing that is performed during a back side attack.

In operation S120, a trench capacitor is formed in the deep trench from the front side of the substrate. The trench capacitor has a second height that is smaller than the first height. The trench capacitor may be modified in the course of back side polishing implemented during a back side attack, altering its capacitance and the dimensions of the trench capacitor, from the original, second, height. This change in capacitance may be detected by a system and method in accordance with principles of inventive concepts, using a sensor, or detector, which includes a ring oscillator and frequency detector, for example. The sensor may be configured to alert a controller circuit, such as a CPU, which, in turn, implements counter-measures to thwart a back side attack.

According to an exemplary embodiment, the trench capacitor may be formed by forming an insulating layer in the deep trench, forming a first electrode on the insulating layer, forming a dielectric layer on the first electrode, and forming a second electrode on the dielectric layer. For example, the first and second electrodes may include polysilicon.

According to another exemplary embodiment, the trench capacitor may be formed by forming an insulating layer in the deep trench, forming a first electrode on the insulating layer, forming a dielectric layer on the first electrode, sequentially forming a barrier layer and a seed layer on the dielectric layer, and forming a second electrode on the seed layer. For example, the first electrode may include polysilicon, and the second electrode may include metal such as copper.

In operation S140, a circuit layer is formed on the front side of the substrate. The circuit layer includes an analog block including a plurality of analog circuits and a digital block including a plurality of digital circuits.

According to an exemplary embodiment, operation S140 may further include forming a detecting circuit that is electrically connected to a trench capacitor in a field region in the analog block or in the digital block and detects a change in capacitance of the trench capacitor according to a second height. In such embodiments, the trench capacitor and the detecting circuit may be employed in a sensor. According to an exemplary embodiment, the detecting circuit may be provided as a ring oscillator that is electrically connected to the trench capacitor.

According to an exemplary embodiment, operation S140 may further include forming a frequency detector that is connected to a sensor and detects a change in frequency that is caused by a change in capacitance of the sensor. The frequency detector may detect a frequency of an output signal of a ring oscillator.

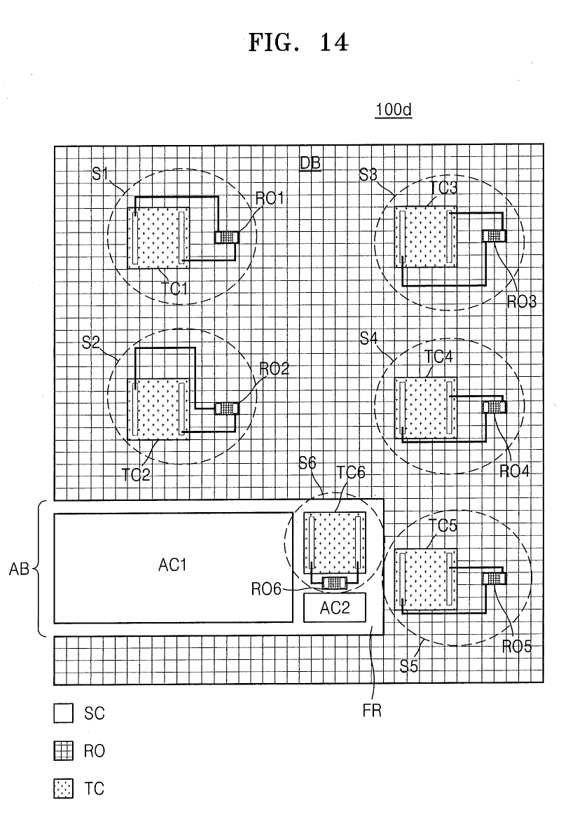

FIG. 16 is a flowchart illustrating an exemplary embodiment of a method of manufacturing a semiconductor device in accordance with principles of inventive concepts.

Referring to FIG. 16, the method of manufacturing the semiconductor device may be a method of manufacturing the semiconductor device 100 shown in FIG. 3A, the semiconductor device 100a shown in FIG, 5, the semiconductor device 100b shown in FIG. 7, or the semiconductor device 100c shown in FIG. 11A. Therefore, the features described with reference to FIGS. 2 to 14 may also be applied to the present embodiment. According to the present embodiment, the semiconductor device may be a smart card chip, i.e., a semiconductor chip embedded in a smart card.

In operation S200, a plurality of trench capacitors may be formed in a substrate. Specifically, operation S200 may be performed by forming a plurality of deep trenches by etching a portion of the substrate, and then forming the plurality of trench capacitors respectively in the plurality of deep trenches. The plurality of deep trenches may be formed such that respective depths of the plurality of deep trenches are greater than a height of the substrate remaining after it is reduced due to back side polishing that is performed during a back side attack.

In operation S220, a plurality of detecting circuits are formed at a front side of the substrate. The plurality of detecting circuits may be electrically connected to the plurality of trench capacitors, respectively, and form a plurality of sensors. According to an exemplary embodiment, in operation S220, the plurality of sensors may be formed such that the plurality of sensors are arranged on the substrate in a matrix form. According to an exemplary embodiment, each of the plurality of sensors may include a ring oscillator.

In operation S240, a frequency detector that is connected to the plurality of detecting circuits is formed at the front side of the substrate. In operation, the frequency detector may detect a change in frequency caused by a change in capacitance of a sensor due to a back side attack. Due to the back side polishing that is performed during the back side attack, a depth of at least one selected from the plurality of trench capacitors decreases, and accordingly, capacitance of at least one trench capacitor decreases. The frequency detector may detect a frequency increase caused by the capacitance decrease and alert a controller, such as a CPU, allowing the controller to implement countermeasures

According to an exemplary embodiment, operation S240 may include forming a logic gate that is commonly connected to the plurality of sensors and detects a change in capacitance of at least one selected from the plurality of trench capacitors, and forming a frequency detector that is connected to the logic gate and detects a change in frequency caused by the change in capacitance. The logic gate may include a NAND gate. According to another exemplary embodiment, the forming of the frequency detector may include forming a plurality of frequency detectors that are respectively connected to the plurality of sensors and detect a change in capacitance. By employing a NAND gate, or equivalent function, a system and method in accordance with principles of inventive concepts may activate a back side attack alert if any of the detectors detect a back side attack operation, as indicated by a decrease in the capacitance of any of the detection capacitors, which may be formed with deep trenches in order to detect back side polishing before the polishing affects other circuitry on the semiconductor.

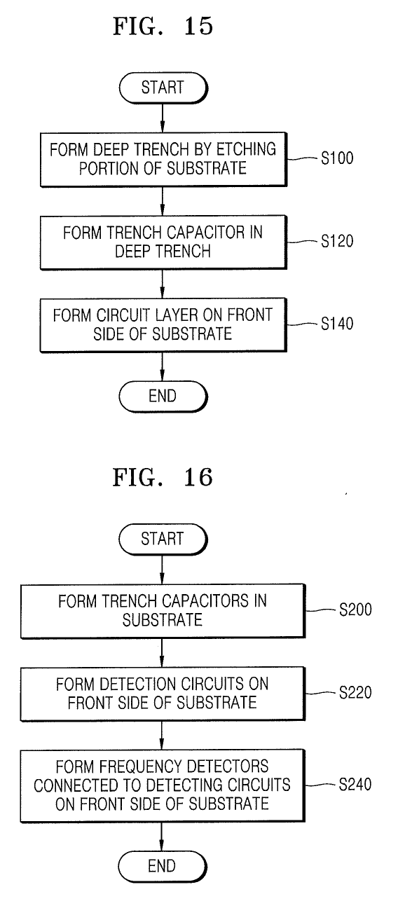

FIG. 17 is a block diagram illustrating an example of a computing system 1000 including a smart card 100, according to an exemplary embodiment.

Referring to FIG. 17, the computing system 1000 includes a host computer 1100 and the smart card 100 in accordance with principles of inventive concepts. The smart card 100 may be formed as the semiconductor device 100 shown in FIG. 3A, the semiconductor device 100a shown in FIG. 5, the semiconductor device 100b shown in FIG. 7, the semiconductor device 100c shown in FIG. 11A, or the semiconductor device 100d shown in FIG. 14.

The host computer 1100 includes a CPU 1110 and a host interface 1120. The smart card 100 includes a card interface 1130, a memory controller 1140, and a memory device 1150. The memory controller 1140 may control a data exchange between the memory device 1150 and the card interface 1130. According to exemplary embodiments, the card interface 1130 may be, but is not limited to, a secure digital (SD) card interface or a multi-media card (MMC) interface.

When the smart card 100 accesses the host interface 1120 of the host computer 1100, the card interface 1130 may provide an interface for exchanging data between the CPU 1110 and the memory controller 1140 according to protocols of the CPU 1110.

According to exemplary embodiments, the card interface 1130 may support a Universal Serial Bus (USB) protocol or an InterChip USB (IC-USB) protocol. Here, the term “card interface” may indicate hardware, software installed in the hardware, or a signal transmission method, which is capable of supporting protocols used by the host computer 1110.

When the smart card 100 accesses the host interface 1120 of the host computer 1110, for example, a personal computer (PC), a tablet PC, a digital camera, a digital audio player, a cellular phone, a consol video game hardware, or a digital set-top box, the host interface 1120 may perform data communication with the memory device 1150 via the card interface 1130 and the memory controller 1140 under the control of the CPU 1110.

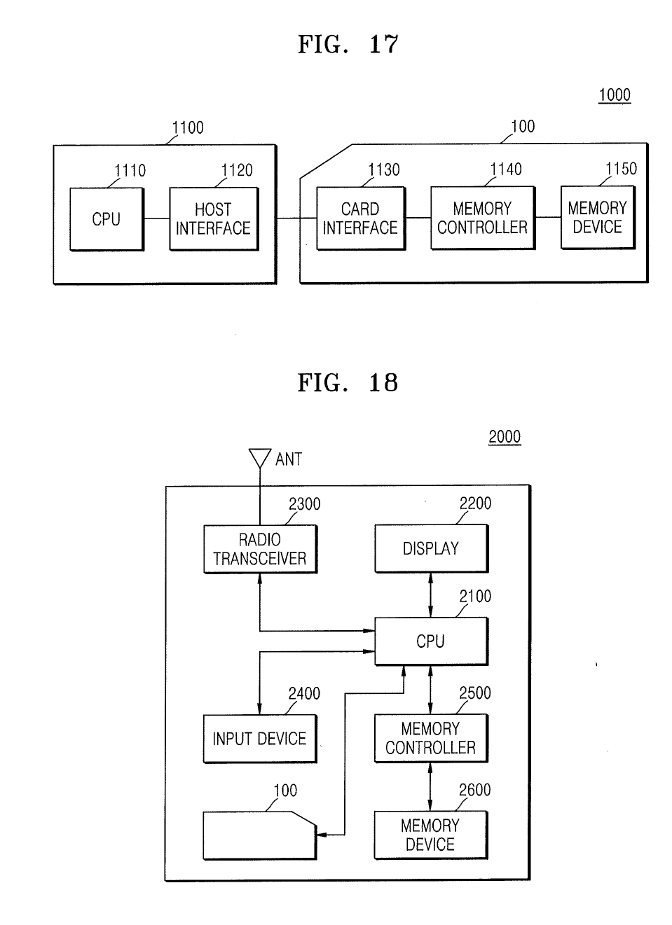

FIG. 18 is a block diagram illustrating another exemplary embodiment of a computing system 2000 including a smart card 100 in accordance with principles of inventive concepts.

Referring to FIG. 18, the computing system 2000 that includes the smart card 100 may be formed as a cellular phone, a smart phone, a personal digital assistant (PDA), or a wireless communication device. The smart card 100 may be formed as the semiconductor device 100 shown in FIG. 3A, the semiconductor device 100a shown in FIG. 5, the semiconductor device 100b shown in FIG. 7, the semiconductor device 100c shown in FIG. 11A, or the semiconductor device 100d shown in FIG. 14.

The computing system 2000 includes a memory device 2600 and a memory controller 2500 that controls the memory device 2600. Under the control of a CPU 2100, the memory controller 2500 may control a data access operation that is performed by the CPU 2100 and the memory device 2600, for example, a write operation, a read operation, a programming operation, or an erase operation.

Data on the memory device 2600 may be displayed via a display 2200 by the CPU 2100 and the memory controller 2500. A radio transceiver 2300 may receive or transmit wireless signals via an antenna ANT. For example, the radio transceiver 2300 may convert a wireless signal received via the antenna ANT into a signal that may be processed in the CPU 2100. The CPU 2100 may process the signal that is output from the radio transceiver 2300, and transmit the processed signal to the memory controller 2500 or the display 2200. The memory controller 2500 may store the signal processed by the CPU 2100 in the memory device 2600.

The radio transceiver 2300 may convert the signal output from the CPU 2100 into a wireless signal, and output the wireless signal to an external device via the antenna ANT. An input device 2400 is a device to which a control signal for controlling the CPU 2100 or data to be processed by the CPU 2100 is input. The input device 2400 may be a pointing device such as a touch pad and a computer mouse, a keypad, or a keyboard.

The CPU 2100 may control the display 2200 such that data output from the memory controller 2500, the radio transceiver 2300, or the input device 2400 is displayed on the display 220.

According to exemplary embodiments, the memory controller 2500, which may control the memory device 2600, may be provided as a part of the CPU 2100 or as a chip separated from the CPU 2100. The smart card 100 may be mounted in or detached from the computing system 2000, for example.

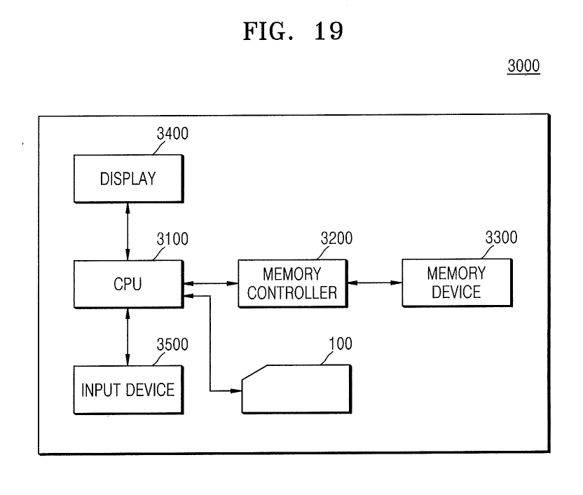

FIG. 19 is a block diagram illustrating another exemplary embodiment of a computing system 3000 including a smart card 100 in accordance with principles of inventive concepts.

Referring to FIG. 19, the computing system 3000 may be a PC, a network server, a tablet PC, a net-book, an e-reader, a PDA, a portable multimedia player (PMP), an MP3 player, or an MP4 player, for example. The smart card 100 may be formed as the semiconductor device 100 shown in FIG. 3A, the semiconductor device 100a shown in FIG. 5, the semiconductor device 100b shown in FIG. 7, the semiconductor device 100c shown in FIG. 11A, or the semiconductor device 100d shown in FIG. 14.

The computing system 3000 includes a CPU 3100, a memory device 3300, a display 3400, an input device 3500, and a memory controller 3200 that may control data process operations that are performed by the memory device 3300.

According to data input via the input device 3500, the CPU 3100 may display data stored in the memory device 3300 via the display 3400. For example, the input device 3500 may be a pointing device such as a touch pad and a computer mouse, a keypad, or a keyboard. The CPU 3100 may control overall operations of the computing system 3000 and operations of the memory controller 3200.

According to exemplary embodiments, the memory controller 3200, which may control the memory device 3300, may be provided as a part of the CPU 3100 or as a chip separated from the CPU 3100. The smart card 100 may be mounted in or detached from the computing system 3000.

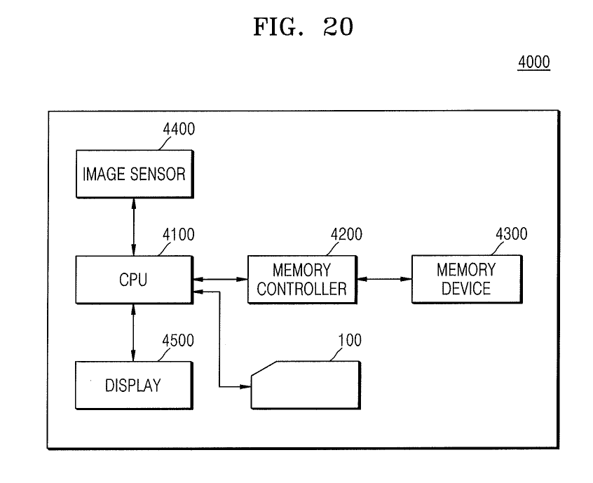

FIG. 20 is a block diagram illustrating an exemplary embodiment of a computing system 4000 including a smart card 100 in accordance with principles of inventive concepts.

Referring to FIG. 20, the computing system 4000 may be an image processor, for example, a digital camera, or a cellular phone or a smart phone including the digital camera. The smart card 100 may be formed as the semiconductor device 100 shown in FIG. 3A, the semiconductor device 100a shown in FIG. 5, the semiconductor device 100b shown in FIG. 7, the semiconductor device 100c shown in FIG. 11A, or the semiconductor device 100d shown in FIG. 14.

The computing system 4000 includes a CPU 4100, a memory device 4300, and a memory controller 4200 that may control a data access operation of the memory device 4300, for example, a write operation, a read operation, a programming operation, or an erase operation. The, computing system 4000 further includes an image sensor 4400 and a display 4500.

The image sensor 4400 of the computing system 4000 may convert an optical image into digital signals and transmit the digital signals to the CPU 4100 or the memory controller 4200. Under the control of the CPU 4100, the digital signals may be displayed via the display 4500 or stored in the memory device 4300 via the memory controller 4200.

Data stored in the memory device 4300 may be displayed via the display 4500 by the CPU 4100 or the memory controller 4200.

According to exemplary embodiments, the memory controller 4200, which may control the memory device 4300, may be provided as a part of the CPU 4100 or as a chip separated from the CPU 4100. The smart card 100 may be mounted in or detached from the computing system 4000.

While inventive concepts have been particularly shown and described with reference to exemplary embodiments thereof, it will be understood that various changes in form and details may be made therein without departing from the spirit and scope of inventive concepts.

1. A smart card comprising:
a substrate comprising a front side and a back side and having a first height between the front side and the back side;
a circuit layer disposed on the front side of the substrate and including an analog block that includes a plurality of analog circuits and a digital block that includes a plurality of digital circuits; and
at least one trench capacitor disposed in the substrate and having a second height extending from the front side of the substrate, wherein the second height is smaller than the first height and may be modified due to a back side attack on the substrate before other circuitry on the smart card is affected by the back side attack.

2. The smart card of claim 1, wherein the circuit layer further includes at least one detecting circuit that is electrically connected to the at least one capacitor and detects a change in capacitance of the at least one trench capacitor, which is caused by a change in the height of the trench capacitor.

3. The smart card of claim 2, wherein the at least one detecting circuit is a ring oscillator that includes a first terminal that is electrically connected to a first electrode of the at least one trench capacitor and a second terminal that is electrically connected to a second electrode of the at least one trench capacitor.

4. The smart card of claim 2, wherein the at least one detecting circuit and the at least one trench capacitor are employed as at least one sensor, and
the at least one trench capacitor is disposed under a field region in the analog block or under the digital block such that the at least one trench capacitor is adjacent to the at least one detecting circuit.

5. The smart card of claim 4, wherein the at least one sensor is implemented as an intellectual property (IP) block and is disposed in the field region in the analog block or in the digital block.

6. The smart card of claim 4, wherein the circuit layer further includes a frequency detector that is connected to the at least one sensor and detects a change in frequency caused by a change in capacitance of the at least one sensor.

7. The smart card of claim 6, wherein the frequency detector is implemented as an intellectual property (IP) block and is disposed in the analog block.

8. The smart card of claim 4, wherein the at least one sensor is implemented as a plurality of sensors arranged in a matrix form on the substrate.

9. The smart card of claim 8, wherein the circuit layer further includes a logic gate that is commonly connected to the plurality of sensors and detects a change in capacitance of at least one selected from the plurality of sensors, and a frequency detector that is connected to the logic gate and detects a change in frequency caused by the change in capacitance.

10. The smart card of claim 9, wherein the logic gate includes a NAND gate.

11. The smart card of claim 8, wherein the circuit layer further includes a plurality of frequency detectors that are respectively connected to the plurality of sensors and detect a change in frequency caused by the change in capacitance of the plurality of sensors.

12. The smart card of claim 1, wherein the at least one trench capacitor includes:
an insulating layer in a deep trench in the substrate;
a first electrode on the insulating layer;
a dielectric layer on the first electrode; and
a second electrode on the dielectric layer.

13. The smart card of claim 12, wherein the first and second electrodes include polysilicon.

14. The smart card of claim 12, wherein the at least one trench capacitor further includes a barrier layer on the dielectric layer, and a seed layer on the barrier layer, and
the second electrode is disposed on the second electrode.

15. The smart card of claim 14, wherein the first electrode includes polysilicon and the second electrode includes metal.

16. A smart card comprising:
a substrate; and
at least one sensor including at least one trench capacitor that detects a back side attack on the substrate, wherein the at least one trench capacitor has a height that changes due to back side polishing that is performed during the back side attack.

17. The smart card of claim 16, wherein the at least one sensor further includes a detecting circuit that is electrically connected to the at least one trench capacitor and detects a change in capacitance of the at least one trench capacitor, which is caused by a change in the height of the at least one trench capacitor.

18. The smart card of claim 17, wherein the at least one detecting circuit is a ring oscillator that comprises a first terminal that is electrically connected to a first electrode of the at least one trench capacitor, and a second terminal that is electrically connected to a second electrode of the at least one trench capacitor.

19. The smart card of claim 16, further comprising a frequency detector that is connected to the at least one sensor and detects a change in frequency caused by a change in capacitance of the at least one sensor.

20. The smart card of claim 16, wherein the at least one sensor is implemented as a plurality of sensors arranged in a matrix on the substrate.

21.-36. (canceled)
